(19) United States
(12) Patent Application Publication
(10) Pub. No.: US 2024/0268044 A1
(43) Pub. Date: Aug. 8, 2024

(54) DISPLAY DEVICE

(71) Applicant: Samsung Display Co., LTD., Yongin-si (KR)

(72) Inventors: YOUNGMIN KIM, Yongin-si (KR); SUNGSANG AHN, Yongin-si (KR)

(73) Assignee: Samsung Display Co., LTD., Yongin-si (KR)

(21) Appl. No.: 18/408,095

(22) Filed: Jan. 9, 2024

(30) Foreign Application Priority Data
Feb. 2, 2023 (KR) 10-2023-0013993

(51) Int. Cl. H05K 5/02

(52) U.S. Cl. CPC H05K 5/0217

(57) ABSTRACT

A display device includes a display module including a flat portion and a bendable portion extending from the flat portion in a first direction, segmental members disposed below the display module, overlapping the bendable portion, and extending in a second direction intersecting the first direction, pattern parts connected to at least one end of the segmental members, respectively and defining an etching groove, and a cover module defining a rail groove accommodating the pattern parts.

### CROSS REFERENCE TO RELATED APPLICATION(S)

This application claims priority to and benefits of Korean Patent Application No. 10-2023-0013993 under 35 U.S.C. § 119, filed in the Korean Intellectual Property Office on Feb. 2, 2023, the entire contents of which are incorporated herein by reference.

### BACKGROUND

### 1. Technical Field

The disclosure relates to a display device. More specifically, the disclosure relates to a slideable display device.

### 2. Description of the Related Art

The display device is a device that displays an image. Recently, a slideable display device capable of reducing or increasing an area of a display area by repeatedly sliding in and out has been spotlighted.

The slideable display device may include a first display area exposed to outside and a second display area extending from the first display area and accommodated inside the slideable display device. In case that the slidable display device is in a slid-in state, the second display area may be accommodated inside the slidable display device. In case that the slidable display device is slid out from the slid-in state, the second display area may be exposed to the outside of the slidable display device.

To accommodate the second display area inside the slideable display device, the second display area may have a curved shape. As the slideable display device is repeatedly slid in and out, the second display area may be repeatedly bent or unfolded.

In case that the slideable display device is repeatedly slid in and out, the slideable display device may be damaged due to repeated bending in the second display area. Accordingly, display defects of the slideable display device may occur and display performance may deteriorate.

The slideable display device may include segment members for sliding the second display area therein. The second display area may slide as the segmental members engage with the rollers and rotate. In this case, a gap between the segmental members and the rail may be relatively large, and as a result, the display device may be damaged in case that the segmental members overlap each other. Accordingly, there is a growing need for a slideable display device including a smooth sliding member without a relatively risk of damage.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device with improved sliding quality.

The technical objectives to be achieved by the disclosure are not limited to those described herein, and other technical objectives that are not mentioned herein would be clearly understood by a person skilled in the art from the description of the disclosure.

A display device according to an embodiment may include a display module including a flat portion and a bendable portion extending from the flat portion in a first direction, segmental members disposed below the display module, overlapping the bendable portion, and extending in a second direction intersecting the first direction, pattern parts connected to at least one end of the segmental members, respectively and defining an etching groove, and a cover module defining a rail groove accommodating the pattern parts.

In an embodiment, the cover module may be fastened to the etching groove of each of the pattern parts.

In an embodiment, the pattern parts may move along the rail groove.

In an embodiment, the cover module may include a first rail and a second rail which define the rail groove.

In an embodiment, the first rail may be spaced apart from the second rail and positioned inside the second rail.

In an embodiment, the etching groove may be defined on an upper portion and lower portion of each of the pattern parts, the etching groove defined on the upper portion of each of the pattern parts may be fastened to the second rail, and the etching groove defined on the lower portion of each of the pattern parts may be fastened to the first rail.

In an embodiment, the cover module may include a first straight portion, a curved portion adjacent to the first straight portion, and a second straight portion adjacent to the curved portion and facing the first straight portion.

In an embodiment, the rail groove may extend from the first straight portion to the second straight portion through the curved portion.

In an embodiment, a shape of the rail groove overlapping the curved portion may be curved.

In an embodiment, a length of the cover module in the first direction may be greater than or substantially equal to a length of the bendable portion in the first direction.

In an embodiment, the segmental members may be spaced apart from each other in a plan view.

In an embodiment, the pattern parts may be spaced apart from each other in a plan view.

In an embodiment, the etching groove may have a shape of one of a rectangle, a triangle, and a semicircle.

In an embodiment, a cross section of an end of each of the pattern parts may be a rectangle.

In an embodiment, the pattern parts may not overlap the display module.

In an embodiment, the cover module may not overlap the display module.

In an embodiment, the pattern parts and the segmental members may be integral with each other.

In an embodiment, the etching groove may extend in the first direction.

In an embodiment, the pattern parts may include first pattern parts each connected to first ends of the segmental members, respectively and second pattern parts connected to second ends of the segmental members, respectively, and each of the first pattern parts and the second pattern parts may define the etching groove.

In an embodiment, the cover module may include a first cover member and a second cover member spaced apart from the first cover member in the second direction, and each of the first cover member and the second cover member may define the rail groove accommodating the pattern parts.

In the display device according to embodiments, since the display device includes pattern parts and a cover module, the pattern parts may move through the cover module, and the display device may slide through the pattern parts. That is, the display device may slide smoothly without an additional member such as a roller. Accordingly, a structure of the display device may be simplified.

In addition, a gap between the first rail and the second rail of the cover module and the pattern parts may be relatively small. Thus, a congestion phenomenon in which pattern parts overlap each other due to the gap may be prevented or reduced. In addition, damage to pattern parts due to the congestion phenomenon may be prevented or reduced. In addition, since the gap is reduced, the pattern parts may move smoothly without shaking. Therefore, sliding quality of the display device may be improved, and display quality of the display device may be improved.

It is to be understood that both the foregoing general description and the following detailed description are explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIGS. 1 and 2 are schematic perspective views illustrating a display device according to embodiments.

FIG. 3 is a schematic plan view illustrating a display device according to embodiments.

FIG. 4 is a schematic exploded perspective view illustrating a part of FIG. 3.

FIG. 5 is a schematic cross-sectional view taken along line I-I′ of FIG. 3.

FIG. 6 is a schematic cross-sectional view illustrating the display panel of FIG. 5.

FIGS. 7 and 8 are schematic views illustrating a sliding method of the display device of FIG. 3.

FIG. 9 is a schematic view taken along line III-III′ of FIG. 3.

FIG. 10 is a schematic perspective view illustrating only one segmental member and one pattern part of FIG. 9.

FIGS. 11 and 12 are schematic cross-sectional views illustrating other examples of FIG. 9.

### DETAILED DESCRIPTION OF THE EMBODIMENTS

The disclosure now will be described more fully hereinafter with reference to the accompanying drawings, in which various embodiments are shown. This disclosure may however, be embodied in many different forms, and should not be construed as limited to the embodiments set forth herein. Rather, these embodiments are provided so that this disclosure will be more thorough and complete, and will convey the scope of the disclosure to those skilled in the art. Like reference numerals and or reference characters refer to like elements throughout.

In this specification, a plane may be defined as a first direction DR1 and a second direction DR2 intersecting the first direction DR1. For example, the first direction DR1 and the second direction DR2 may be perpendicular to each other. A direction normal to the plane, that is, a thickness direction of the display device 10 may be the third direction DR3. In other words, the third direction DR3 may be perpendicular to each of the first direction DR1 and a second direction DR2.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

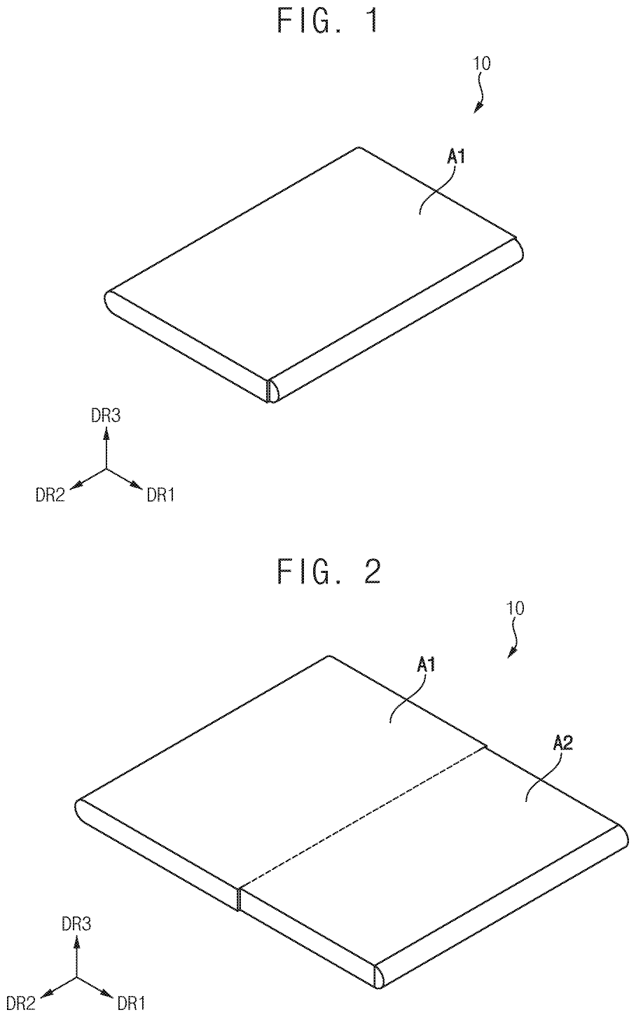

FIGS. 1 and 2 are schematic perspective views illustrating a display device according to embodiments.

Referring to FIGS. 1 and 2, the display device 10 may be a slideable display device. The display device 10 may include areas, such as a first area A1 and a second area A2.

The display device 10 may slide-out in the first direction DR1 and may slide-in in a direction opposite to the first direction DR1.

In an embodiment, the first area A1 and the second area A2 may be display areas. The first area A1 may be an area which is always exposed to a user of the display device 10. The second area A2 may extend from the first area A1. For example, the second area A2 may extend from the first area A1 in the first direction DR1.

The second area A2 may be an area which is inside the display device 10 in case that the display device 10 is not in a first configuration (e.g., slid-in state or folded state), and may be exposed to the user of the display device 10 in case that the display device 10 is in second configuration (e.g., slid-out state or unfolded state). Each of the first area A1 and the second area A2 may display an image.

Specifically, as shown in FIG. 1, in case that the display device 10 is in a slid-in state, the second area A2 may be accommodated inside the display device 10. In this case, the user of the display device 10 may view the image displayed in the first area A1.

As shown in FIG. 2, in case that a portion of the display device 10 is in a slid-out state, a portion of the second area A2 may be exposed. In this case, the user of the display device 10 may view the image displayed in the first area A1 and the image displayed in the portion of the second area A2.

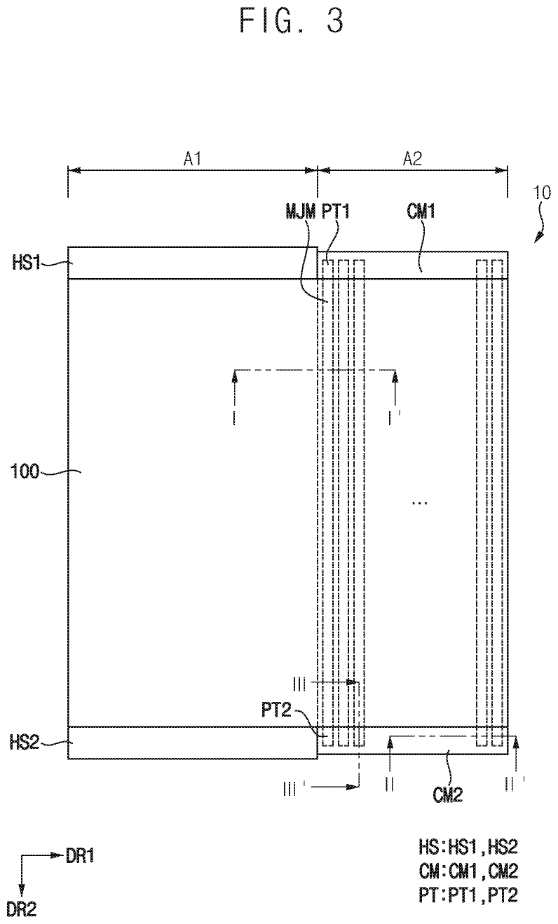

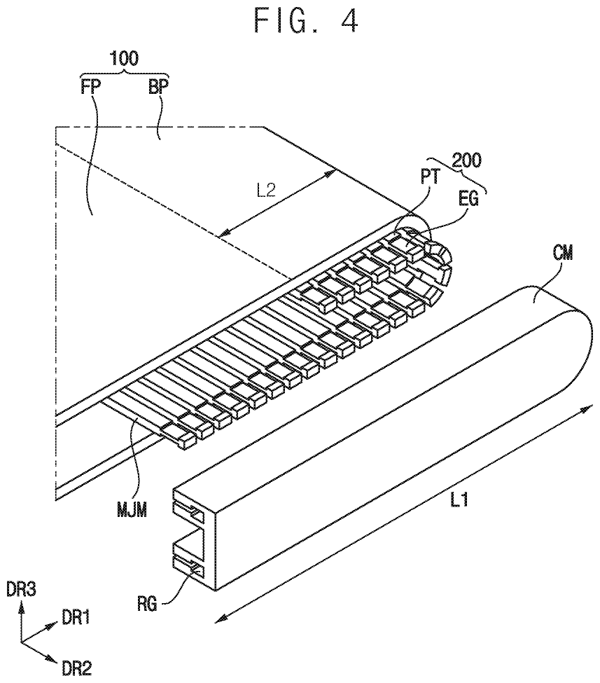

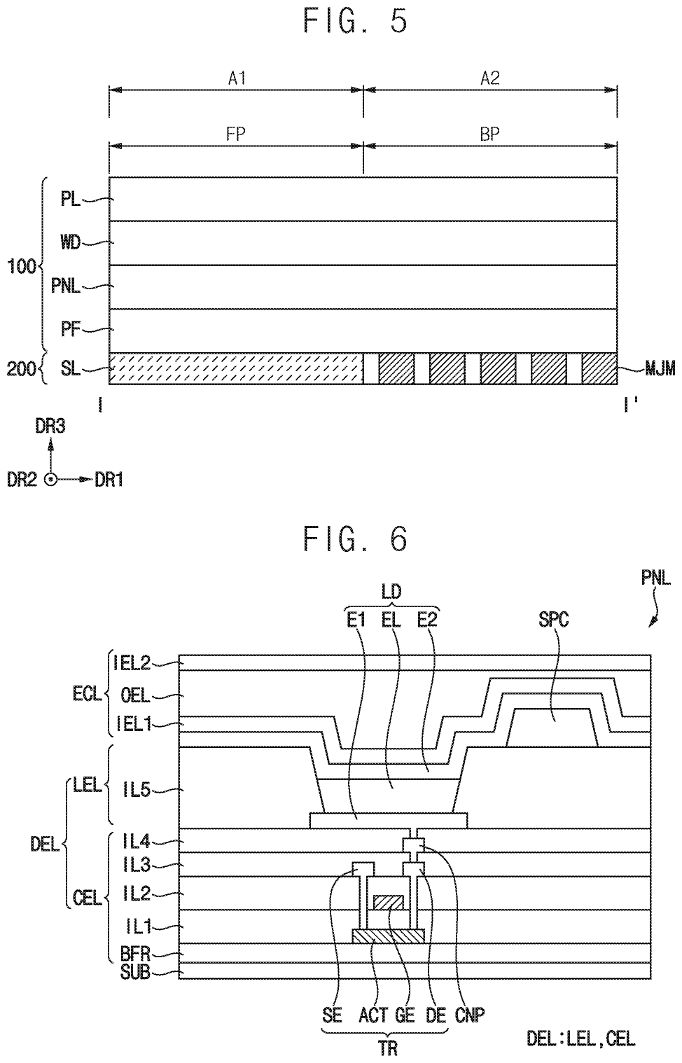

FIG. 3 is a schematic plan view illustrating a display device according to embodiments. FIG. 4 is a schematic exploded perspective view illustrating a part of FIG. 3. FIG. 5 is a schematic cross-sectional view taken along line I-I′ of FIG. 3.

For example, FIG. 4 may be a schematic view illustrating only one end of a display module 100 of FIG. 3, a lower structure 200 and a cover module CM.

Referring to FIGS. 3 to 5, the display device 10 may include a display module 100, a lower structure 200, a cover module CM, and/or a housing module HS.

The display module 100 may include a flat portion FP and a bendable portion BP. The flat portion FP may be a portion overlapping the first area A1 in the display module 100. The flat portion FP may be an area exposed to outside and may have a flat shape.

The bendable portion BP may be a portion overlapping the second area A2 in the display module 100. The bendable portion BP may be flexible. The bendable portion BP may extend in the first direction DR1 from the flat portion FP. The bendable portion BP may be exposed to the outside or accommodated inside as the display device 10 slides.

The display module 100 may include a protective film PF, a display panel PNL, a window WD, and/or a protective layer PL.

The display panel PNL may display an image. Examples of the display panel PNL may include an organic light emitting display panel, an inorganic light emitting display panel, a quantum dot light emitting display panel, a micro LED display panel, a nano LED display panel, a plasma display panel, a field emission display panel, a cathode ray display panel, a liquid crystal display panel, and an electrical display panel, a migration display panel, or the like.

The protective film PF may be disposed below the display panel PNL. The protective film PF may reduce stress applied to the display panel PNL in case that the display panel PNL is folded or bent. The protective film PF may prevent penetration of moisture into the display panel PNL and absorb external impact.

The protective film PF may be a plastic film. For example, examples of the plastic film included in the protective film PF may include polyimide (PI), polyethylene terephthalate (PET), polycarbonate (PC), polypropylene (PP), polyethersulfone (PES), polymethyl methacrylate (PMMA), triacetyl cellulose (TAC), cyclo olefin polymer (COP), the like, or a combination thereof.

The window WD may be disposed on the display panel PNL. The window WD may protect the display panel PNL. The window WD may include a transparent material. For example, the window WD may include glass, plastic, the like, or a combination thereof.

In case that the window WD includes glass, the glass may be ultra-thin glass (UTG). The window WD may be flexible. For example, in case that the glass is an ultra-thin film glass, the glass may be flexible.

The protective layer PL may be disposed on the window WD. The protective layer PL may perform at least one function selected from preventing scattering of the window WD, absorbing shock of the window WD, preventing puncture of the window WD, preventing fingerprints of the window WD, and preventing glare of the window WD. The protective layer PL may include a transparent polymer film. For example, examples of the transparent polymer film included in the protective layer PL may include polyethylene terephthalate (PET), polyethylene naphthalate (PEN), polyethersulfone (PES), polyimide (PI), polyarylate (PAR), polycarbonate (PC), polymethyl methacrylate (PMMA), cyclo olefin polymer (COP), the like, or a combination thereof.

In addition, embodiments according to the disclosure are not limited thereto, and the display panel PNL may further include a polarization layer disposed on the display panel PNL and a buffer member disposed under the protective film PF. The polarization layer may polarize light passing through the polarization layer and reduce reflection of external light of the display device 10. The buffer member may protect the display panel PNL by buffering an external shock that may be applied to the display panel PNL.

In an embodiment, the lower structure 200 may be disposed below the display module 100. The lower structure 200 may include a support layer SL, segmental members MJM, and/or pattern parts PT.

The support layer SL may be disposed below the display module 100 and may overlap the flat portion FP. The support layer SL and the segmental members MJM may be disposed on a same layer. The support layer SL may support the display module 100. The support layer SL may include a material having relatively high rigidity. However, the disclosure is not limited thereto, and in other embodiments, for example, the support layer SL may be omitted or may include different materials.

In an embodiment, the segmental members MJM may be disposed below the display module 100 and may overlap the bendable portion BP. The segmental members MJM may guide a movement of the bendable portion BP. The segmental members MJM may allow the bendable portion BP of the display module 100 to move while maintaining a smooth shape that is not deformed convexly.

The segmental members MJM may be spaced apart from each other in a plan view. For example, the segmental members MJM may not overlap each other in a plan view. However, the disclosure is not limited thereto, and the segmental members MJM may contact each other in a plan view. The segmental members MJM may extend in the second direction DR2.

In an embodiment, the pattern parts PT may be connected to at least one end of the segmental members MJM, respectively. For example, each of the pattern parts PT may be connected to both ends of the segmental members MJM (see FIG. 10). However, the disclosure is not limited thereto, and in another embodiment, the pattern parts PT may be connected only to one end of the segmental members MJM.

The pattern parts PT may be integrally formed with the segmental members MJM, respectively. For example, the pattern parts PT may be parts extending from the segmental members MJM. However, the disclosure is not limited thereto, and in another embodiment, the pattern parts PT and the segmental members MJM may be separately formed and connected.

The segmental members MJM may extend in the second direction DR2. Also, the pattern parts PT may be spaced apart from each other in a plan view. For example, the pattern parts PT may not overlap each other in a plan view. The pattern parts PT may be connected to each other through a bridge pattern or the like. However, the disclosure is not limited thereto.

In a plan view, the pattern parts PT may not overlap the display module 100. For example, the segmental members MJM may overlap the display module 100 in a plan view or the third direction DR3, and the pattern parts PT may protrude from the display module 100 in the second direction DR2 and may not overlap the display module 100 in a plan view of the third direction.

In an embodiment, the pattern parts PT may define etching grooves EG. The etching grooves EG may extend in the first direction DR1. The etching grooves EG may not overlap the display module 100 (e.g., in a plan view or third direction DR3).

In an embodiment, the cover module CM may accommodate the pattern parts PT. Specifically, the cover module CM may define a rail groove RG. The rail groove RG may accommodate the pattern parts PT. The cover module CM may not overlap the display module 100.

A length L1 of the cover module CM in the first direction DR1 may be greater than or equal to a length L2 of the bendable portion BP in the first direction DR1. For example, the length L1 of the cover module CM in the first direction DR1 may be greater than or equal to a maximum length L2 of the bendable portion BP in the first direction DR1. For example, the maximum length L2 of the bendable portion BP in the first direction DR1 may be a sum of lengths of all of the segmental members MJM in the first direction DR1. Thus, even in case that the bendable portion BP has the maximum length L2 in the first direction DR1, the cover module CM may accommodate all of the segmental members MJM.

The housing module HS may accommodate the cover module CM. In case that the cover module CM is slid-out, the cover module CM may be taken out of the housing module HS, and in case that the cover module CM is slid-in, the cover module CM may be housed in the housing module HS.

In an embodiment, the pattern parts PT may be connected to both ends of the segmental members MJM. For example, the pattern parts PT may include first pattern parts PT1 and second pattern parts PT2. Similarly, the cover module CM may be disposed above and below the display module 100. For example, the cover module CM may include a first cover member CM1 accommodating the first pattern parts PT1 and a second cover member CM2 accommodating the second pattern parts PT2. The housing module HS may also be disposed above and below the display module 100. For example, the housing module HS may include a first housing member HS1 accommodating the first cover member CM1 and a second housing member HS2 accommodating the second cover member CM2.

The first pattern parts PT1 may be connected to one ends of the segmental members MJM, respectively. The second pattern parts PT2 may be connected to the other ends of the segmental members MJM, respectively. For example, the second pattern parts PT2 may be spaced apart from the first pattern parts PT1 in the second direction DR2. Each of the first pattern parts PT1 and the second pattern parts PT2 may define the etching groove EG.

The second cover member CM2 may be spaced apart from the first cover member CM1 in the second direction DR2. Each of the first cover member CM1 and the second cover member CM2 may define the rail groove RG. For example, the first cover member CM1 may accommodate the first pattern parts PT1. The second cover member CM2 may accommodate the second pattern parts PT2. For example, the rail groove RG of the first cover member CM1 may accommodate the first pattern parts PT1, and the rail groove RG of the second cover member CM2 may accommodate the second pattern parts PT2.

FIG. 6 is a schematic cross-sectional view illustrating the display panel of FIG. 5.

Referring to FIG. 6, the display panel PNL may include a substrate SUB, a display element layer DEL, and/or an encapsulation layer ECL. The display element layer DEL may include a circuit element layer CEL and a light emitting element layer LEL.

The circuit element layer CEL may be disposed on the substrate SUB, and include a buffer layer BFR, at least one transistor TR, a connection electrode CNP, a first insulating layer IL1, a second insulating layer IL2, a third insulating layer IL3, and/or a fourth insulating layer IL4. The transistor TR may include an active layer ACT, a gate electrode GE, a source electrode SE, and a drain electrode DE. The light emitting element layer LEL may be disposed on the circuit element layer CEL, and may include a fifth insulating layer IL5, a spacer SPC, and/or a light emitting diode LD. The light emitting diode LD may include a first electrode E1, an emission layer EL, and a second electrode E2.

The buffer layer BFR may be disposed on the substrate SUB. The buffer layer BFR may prevent diffusion of metal atoms or impurities from the substrate SUB into the active layer ACT.

The active layer ACT may be disposed on the substrate SUB. The active layer ACT may be divided into a source area and a drain area doped with impurities and a channel area between the source area and the drain area.

The first insulating layer IL1 may be disposed on the buffer layer BFR. The first insulating layer IL1 may cover the active layer ACT and may be formed to have substantially a same thickness along a profile of the active layer ACT. However, the disclosure is not limited thereto, and the first insulating layer IL1 may be disposed on the active layer ACT in a pattern form. For example, the first insulating layer IL1 may include an organic material and/or an inorganic material.

The gate electrode GE may be disposed on the first insulating layer IL1. In an embodiment, the gate electrode GE may overlap the channel area of the active layer ACT.

The second insulating layer IL2 may be disposed on the first insulating layer IL1. The second insulating layer IL2 may cover the gate electrode GE and may be disposed with substantially a same thickness along a profile of the gate electrode GE. However, it is not limited thereto.

The source electrode SE and the drain electrode DE may be disposed on the second insulating layer IL2. The source electrode SE may contact the source area of the active layer ACT through a first contact hole formed in the first and second insulating layers IL1 and IL2. The drain electrode DE may contact the drain area of the active layer ACT through a second contact hole formed in the first and second insulating layers IL1 and IL2.

The third insulating layer IL3 may be disposed on the second insulating layer IL2. The third insulating layer IL3 may cover the source and drain electrodes SE and DE, and have a substantially flat upper surface without having a step around the source and drain electrodes SE and DE. For example, the third insulating layer IL3 may include an organic material and/or inorganic material.

The connection electrode CNP may be disposed on the third insulating layer IL3. The connection electrode CNP may contact the source electrode SE or the drain electrode DE through a contact hole formed in the third insulating layer IL3.

The fourth insulating layer IL4 may be disposed on the third insulating layer IL3. The fourth insulating layer IL4 may cover the connection electrode CNP and may have a substantially flat upper surface without having a step around the source and drain electrodes SE and DE. For example, the fourth insulating layer IL4 may include an organic material and/or an inorganic material.

The first electrode E1 may be disposed on the fourth insulating layer IL4. The first electrode E1 may have reflective or light-transmitting properties. For example, the first electrode E1 may include a conductive material such as metal.

The first electrode E1 may contact the connection electrode CNP through a fourth contact hole formed in the fourth insulating layer IL4. Through this, the first electrode E1 may be connected to the transistor TR.

The fifth insulating layer IL5 may be disposed on the fourth insulating layer IL4, and an opening exposing an upper surface of the first electrode E1 may be defined in the fifth insulating layer IL5. For example, the fifth insulating layer IL5 may include an organic material and/or an inorganic material.

The spacer SPC may be disposed on the fifth insulating layer IL5. For example, the spacer SPC may include an organic material or an inorganic material. The spacer SPC may maintain a gap between the encapsulation layer ECL and the substrate SUB.

The spacer SPC may include a material different from a material of the fifth insulating layer IL5. The spacer SPC may be formed after the fifth insulating layer IL5 is formed. However, embodiments according to the disclosure are not limited thereto, and the spacer SPC may include a same material as the fifth insulating layer IL5.

The emission layer EL may be disposed on the first electrode E1. The light emitting layer EL may be disposed in the opening formed in the fifth insulating layer IL5. In an embodiment, the emission layer EL may have a multilayer structure including a hole injection layer, a hole transport layer, an organic emission layer, an electron transport layer, and an electron injection layer. The organic emission layer may include a light emitting material.

The second electrode E2 may cover the emission layer EL and may be disposed on the fifth insulating layer IL5 and the spacer SPC. In an embodiment, the second electrode E2 may have a plate shape. In addition, the second electrode E2 may have light transmitting or reflecting properties. For example, the second electrode E2 may include metal.

The encapsulation layer ECL may prevent penetration of moisture and oxygen into the light emitting diode LD from outside. For example, the encapsulation layer ECL may include a first inorganic encapsulation layer IEL1, an organic encapsulation layer OEL, and/or a second inorganic encapsulation layer IEL2.

The first inorganic encapsulation layer IEL1 may be disposed on the second electrode E2 with substantially a same thickness along a profile of the second electrode E2. The organic encapsulation layer OEL may be disposed on the first inorganic encapsulation layer IEL1, and may have a substantially flat upper surface without having a step around the first inorganic encapsulation layer IEL1. The second inorganic encapsulation layer IEL2 may be disposed on the organic encapsulation layer OEL.

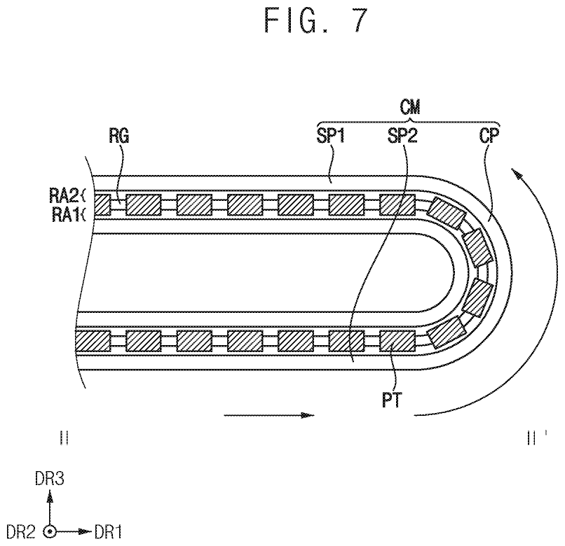

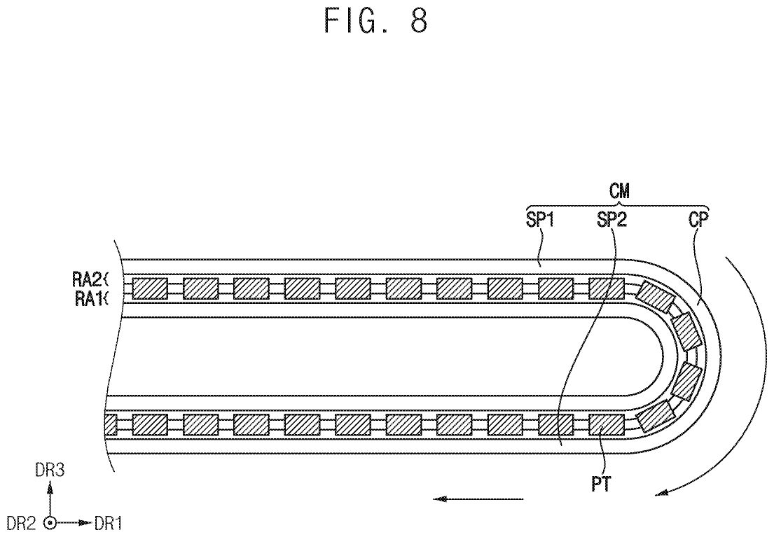

FIGS. 7 and 8 are schematic views illustrating a sliding method of the display device of FIG. 3. For example, FIGS. 7 and 8 are cross-sectional views taken along line II-II′ of FIG. 3. Specifically, FIG. 7 is a cross-sectional view illustrating a part of the display device of FIG. 1, and FIG. 8 is a cross-sectional view illustrating a part of the display device of FIG. 2.

Referring to FIGS. 7 and 8, the display device 10 may slide through the cover module CM. For example, in case that the cover module CM is pulled in the first direction DR1, the display device 10 may be slid out (see FIG. 7), and the cover module CM may be moved to the first direction DR1. In case that the cover module CM is pushed in a direction opposite to the first direction DR1, the display device 10 may be slid in (see FIG. 8).

In an embodiment, the pattern parts PT may be fastened to the rail groove RG. Also, the cover module CM may be fastened to the etching groove EG of each of the pattern parts PT. Accordingly, the pattern parts PT may move along the rail groove RG. That is, the rail groove RG may guide the movement of the pattern parts PT.

In an embodiment, a cross section of one end of each of the pattern parts PT may be a rectangle. However, the disclosure is not limited thereto.

The cover module CM may include a first straight portion SP1, a curved portion CP, and a second straight portion SP2. The second straight portion SP2 may face the first straight portion SP1, the curved portion CP may be adjacent to the first straight portion SP1 and the second straight portion SP2 and positioned at one end of the first straight portion SP1 and one end of the second straight portion SP2. The rail groove RG may extend from the first straight portion SP1 to the second straight portion SP2 through the curved portion CP.

A shape of the rail groove RG overlapping each of the first straight portion SP1 and the second straight portion SP2 may be a straight line. A shape of the rail groove RG overlapping the curved portion CP may be a curved.

In case that the display device 10 is in a slid-in state, most of the pattern parts PT may be disposed on the second straight portion SP2. However, the disclosure is not limited thereto, and the pattern parts PT may be partially disposed on portions of the curved portion CP and the first straight portion SP1. Also, in case that the display device 10 is in a slid-out state, most of the pattern parts PT may be disposed on the first straight portion SP1. However, the disclosure is not limited thereto, and the pattern portions PT may be partially disposed on portions of the curved portion CP and the second straight portion SP2.

For example, in case that the display device 10 is slid out, the pattern parts PT located on the second straight portion SP2 may move to the first straight portion SP1 through the curved portion CP (see FIG. 7). Also, in case that the display device 10 is slid-in, the pattern parts PT located on the first straight portion SP1 may move to the second straight portion SP2 through the curved portion CP (see FIG. 8).

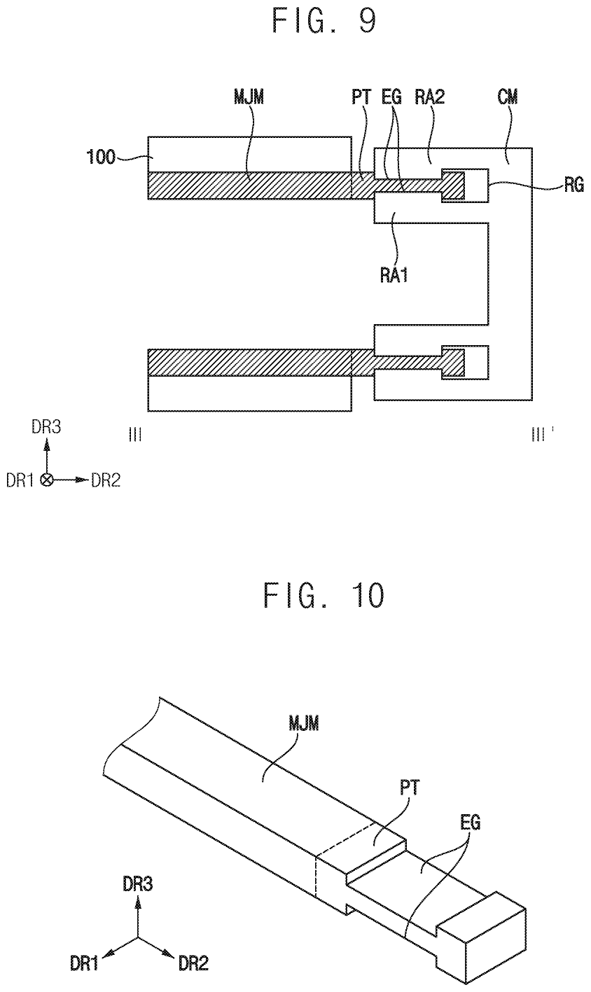

FIG. 9 is a schematic view taken along line III-III′ of FIG. 3. FIG. 10 is a schematic perspective view illustrating only one segmental member and one pattern part of FIG. 9.

Referring to FIGS. 9 and 10, the etching groove EG may be defined at upper and lower portions of the pattern parts PT, respectively. Also, the cover module CM may include a first rail RA1 and a second rail RA2. The first rail RA1 and the second rail RA2 may define the rail groove RG. Therefore, the first rail RA1 and the second rail RA2 may be spaced apart from each other. The first rail RA1 may be positioned inside the second rail RA2.

The etching groove EG defined on each of the pattern parts PT may be fastened to the second rail RA2. The etching groove EG defined under each of the pattern parts PT may be fastened to the first rail RA1. Accordingly, the pattern parts PT may be fastened to the first rail RA1 and the second rail RA2 to move along the first rail RA1 and the second rail RA2.

The etching groove EG may have a shape of one of a rectangle, a triangle, and a semicircle. Specifically, the cross section of the etching groove EG may have one of a quadrangular shape, a triangular shape, and a semicircular shape. For example, the etching groove EG may have a rectangular shape. For example, since the etching groove EG has a rectangular shape, each of the pattern parts PT may have an H shape. However, the disclosure is not limited thereto, and each of the pattern parts PT may have various shapes.

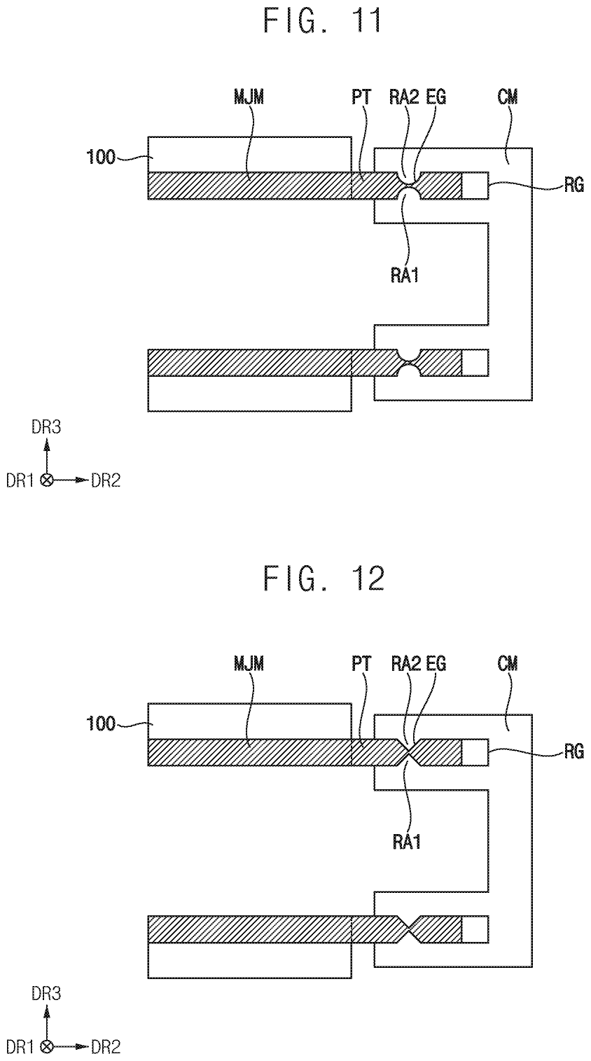

FIGS. 11 and 12 are schematic cross-sectional views illustrating other examples of FIG. 9.

The display device described with reference to FIGS. 11 and 12 may be different from the display device described with reference to FIG. 9 at least in a shape of the etching groove.

Referring to FIG. 11, the etching groove EG may have a shape of, e.g., one of a rectangle, a triangle, and a semicircle. For example, the etching groove EG may have a semicircular shape. For example, since the etching groove EG has a semicircular shape, each of the pattern parts PT may have a curved surface. However, the disclosure is not limited thereto, and each of the pattern parts PT may have various shapes.

Referring to FIG. 12, the etching groove EG may have a shape of, e.g., one of a rectangle, a triangle, and a semicircle. For example, the etching groove EG may have a triangular shape. For example, since the etching groove EG has a triangular shape, each of the pattern parts PT may have planes adjacent to each other. However, the disclosure is not limited thereto, and each of the pattern parts PT may have various shapes.

In an embodiment, since the display device 10 includes the pattern parts PT and the cover module CM, the pattern parts PT may move through the cover module CM, and through this, the display device 10 may slide. For example, the display device 10 may slide smoothly without an additional member such as a roller. Thus, the structure of the display device 10 may be simplified.

Also, a gap in the third direction DR3 between the first rail RA1 and the cover module CM and a gap in the third direction DR3 between the second rail RA2 and the cover module CM may be relatively small. Accordingly, a congestion phenomenon in which the pattern parts PT overlap each other due to the gap may be prevented or reduced. Also, damage to the pattern parts PT due to the congestion phenomenon may be prevented or reduced. In addition, since the gap is reduced, the pattern parts PT may move smoothly without shaking. Thus, sliding quality of the display device 10 may be improved.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display module including a flat portion and a bendable portion extending from the flat portion in a first direction;
segmental members disposed below the display module, overlapping the bendable portion, and extending in a second direction intersecting the first direction;
pattern parts connected to at least one end of the segmental members, respectively, and defining an etching groove; and
a cover module defining a rail groove accommodating the pattern parts.

2. The display device of claim 1, wherein the cover module is fastened to the etching groove of each of the pattern parts.

3. The display device of claim 1, wherein the pattern parts move along the rail groove.

4. The display device of claim 1, wherein the cover module includes a first rail and a second rail which define the rail groove.

5. The display device of claim 4, wherein the first rail is spaced apart from the second rail and positioned inside the second rail.

6. The display device of claim 4, wherein
the etching groove is defined on an upper portion and lower portion of each of the pattern parts,
the etching groove defined on the upper portion of each of the pattern parts is fastened to the second rail, and
the etching groove defined on the lower portion of each of the pattern parts is fastened to the first rail.

7. The display device of claim 1, wherein the cover module includes:
a first straight portion;
a curved portion adjacent to the first straight portion; and
a second straight portion adjacent to the curved portion and facing the first straight portion.

8. The display device of claim 7, wherein the rail groove extends from the first straight portion to the second straight portion through the curved portion.

9. The display device of claim 8, wherein a shape of the rail groove overlapping the curved portion is curved.

10. The display device of claim 1, wherein a length of the cover module in the first direction is greater than or substantially equal to a length of the bendable portion in the first direction.

11. The display device of claim 1, wherein the segmental members are spaced apart from each other in a plan view.

12. The display device of claim 1, wherein the pattern parts are spaced apart from each other in a plan view.

13. The display device of claim 1, wherein the etching groove has a shape of one of a rectangle, a triangle, and a semicircle.

14. The display device of claim 1, wherein a cross section of an end of each of the pattern parts is a rectangle.

15. The display device of claim 1, wherein the pattern parts do not overlap the display module.

16. The display device of claim 1, wherein the cover module does not overlap the display module.

17. The display device of claim 1, wherein the pattern parts and the segmental members are integral with each other.

18. The display device of claim 1, wherein the etching groove extends in the first direction.

19. The display device of claim 1, wherein the pattern parts include:
first pattern parts each connected to first ends of the segmental members, respectively; and
second pattern parts connected to second ends of the segmental members, respectively, and
each of the first pattern parts and the second pattern parts defines the etching groove.

20. The display device of claim 1, wherein
the cover module includes a first cover member and a second cover member spaced apart from the first cover member in the second direction, and
each of the first cover member and the second cover member defines the rail groove accommodating the pattern parts.
